(19) United States
(12) Patent Application Publication
(10) Pub. No.: US 2025/0046754 A1
(43) Pub. Date: Feb. 6, 2025

(54) SEMICONDUCTOR PACKAGE

(71) Applicant: Samsung Electronics Co., Ltd., Suwon-si (KR)

(72) Inventors: Hyun-Mook Choi, Suwon-si (KR); Keum Hyo Kang, Suwon-si (KR)

(21) Appl. No.: 18/664,499

(22) Filed: May 15, 2024

(30) Foreign Application Priority Data
Aug. 3, 2023 (KR) 10-2023-0101389

(51) Int. Cl. H01L 25/065; H01L 23/00; H01L 23/42; H01L 23/48; H01L 23/538; H10B 80/00

(52) U.S. Cl. CPC H01L 25/0652; H01L 23/42; H01L 23/481; H01L 23/5386; H01L 24/16; H01L 24/32; H10B 80/00; H01L 2224/16145; H01L 2224/16225; H01L 2224/32145; H01L 2224/32245

(57) ABSTRACT

A semiconductor package includes a package substrate including a trench; a first chip structure including a first buffer chip and a plurality of first semiconductor chips on the first buffer chip; and a second chip structure including a second buffer chip and a second semiconductor chip on the second buffer chip, wherein one of the first and second chip structures is on the trench, the other one of the first and second chip structures is on a top surface of the package substrate, a first physical layer (PHY) region of the first buffer chip overlaps with a second PHY region of the second buffer chip in a direction perpendicular to the top surface of the package substrate.

### CROSS-REFERENCE TO RELATED APPLICATION

This application claims priority under 35 U.S.C. 119 from Korean Patent Application No. 10-2023-0101389 filed on Aug. 3, 2023, in the Korean Intellectual Property Office, the contents of which in their entirety are herein incorporated by reference.

### BACKGROUND

The present disclosure relates to a semiconductor package.

As the electronics industry advances, electronic devices are gradually becoming smaller and more multifunctional. Consequently, there is an increasing demand for higher capacity and faster memory in electronic devices. To address this need, various technologies are being proposed to both miniaturize semiconductor packages and enhance memory capacity and speed.

In response to this trend, system-in-package technology is gaining attention. This involves integrating semiconductor memory devices within a single package structure, allowing a single semiconductor package product to perform high-speed operations, handle large-scale data processing, and support multifunctional operations. Additionally, the high bandwidth memory (HBM) technology is garnering attention, wherein multiple semiconductor chips are vertically stacked using through silicon vias (TSVs) to achieve high-capacity memory.

### SUMMARY

Aspects of the present disclosure provide a semiconductor package with an improved product reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some example embodiments of the present inventive concepts, a semiconductor package includes a package substrate including a trench; a first chip structure including a first buffer chip and a plurality of first semiconductor chips on the first buffer chip; and a second chip structure including a second buffer chip and a second semiconductor chip on the second buffer chip, wherein one of the first and second chip structures is on the trench, the other one of the first and second chip structures is on a top surface of the package substrate, and a first physical layer (PHY) region of the first buffer chip overlaps with a second PHY region of the second buffer chip in a direction perpendicular to the top surface of the package substrate.

According to some example embodiments of the present inventive concepts, a semiconductor package includes a package substrate; a first chip structure including a first buffer chip and a plurality of first semiconductor chips on the first buffer chip; a second chip structure including a second buffer chip and a second semiconductor chip on the second buffer chip; and a third semiconductor chip on a top surface of the package substrate, wherein one of the first and second chip structures is on the top surface of the package substrate, the other one of the first and second chip structures is on the third semiconductor chip, and a first physical layer (PHY) region of the first buffer chip overlaps with a second PHY region of the second buffer chip in a direction perpendicular to the top surface of the package substrate.

According to some example embodiments of the present inventive concepts, a semiconductor package includes a package substrate including a trench; a first chip structure on the package substrate, the first chip structure including a first buffer chip, which includes a first physical layer (PHY) region, and a plurality of first semiconductor chips on the first buffer chip; a second chip structure on the package substrate, the second chip structure including a second buffer chip, which includes a second PHY region, and a plurality of second semiconductor chips on the second buffer chip; a thermal transfer material layer on the second chip structure; a first heat dissipation member on the thermal transfer material layer; a molding layer on the package substrate, the molding layer on the first chip structure and the first heat dissipation member; and a second heat dissipation member on the molding layer, wherein the first PHY region overlaps with the second PHY region in a direction perpendicular to a top surface of the package substrate, one of the first and second buffer chips is in the trench, and the other one of the first and second buffer chips is on the top surface of the package substrate.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is a schematic view of a semiconductor package according to some embodiments of the present disclosure;

FIG. 2 is a cross-sectional view taken along line I-I′ of FIG. 1;

FIGS. 3 through 5 are cross-sectional views of semiconductor packages according to some embodiments of the present disclosure;

FIGS. 6 through 9 are cross-sectional views of semiconductor packages according to some embodiments of the present disclosure;

FIGS. 10 through 13 are cross-sectional views illustrating intermediate steps of a method of fabricating a semiconductor package according to some embodiments of the present disclosure; and

FIG. 14 is a schematic view of a semiconductor package according to some embodiments of the present disclosure.

### DETAILED DESCRIPTION

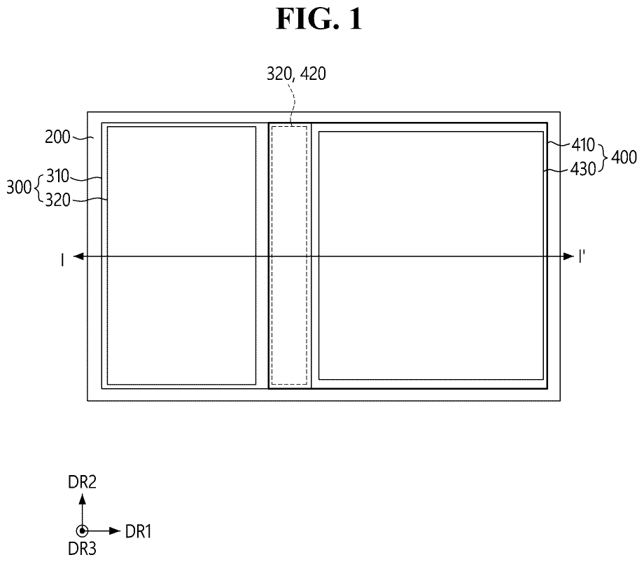

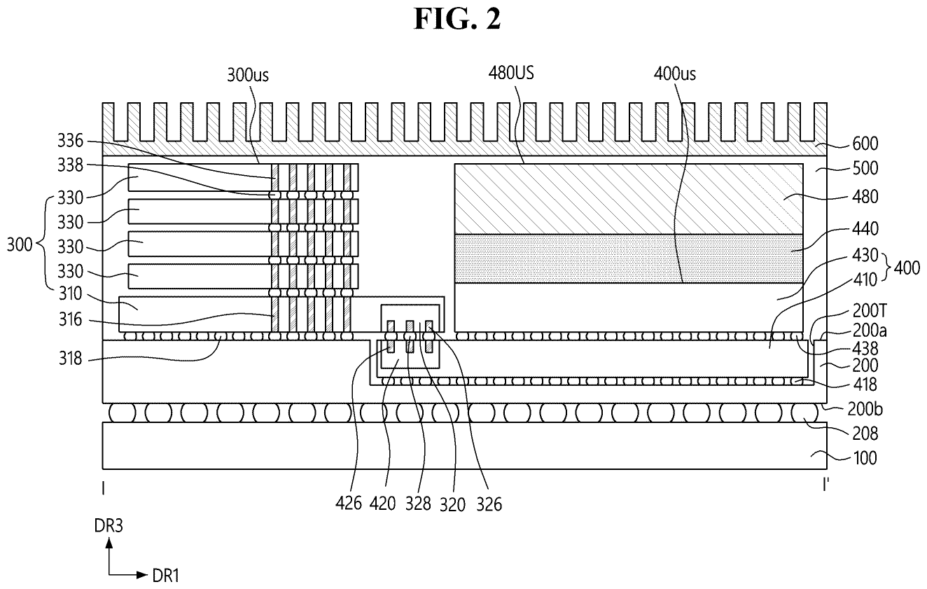

FIG. 1 is a schematic view of a semiconductor package according to some embodiments of the present disclosure. FIG. 2 is a cross-sectional view taken along line I-I′ of FIG. 1.

Referring to FIGS. 1 and 2, the semiconductor package according to some embodiments of the present disclosure includes a main board 100, a package substrate 200, a first chip structure 300, a second chip structure 400, a thermal transfer material layer 440, a first heat dissipation member 480, a molding layer 500, and a second heat dissipation member 600.

The package substrate 200 includes a top surface 200a and a bottom surface 200b, which are opposite to each other in a third direction DR3. First and second directions DR1 and DR2 are directions parallel to the top and bottom surfaces 200a and 200b of the package substrate 200. The first and second directions DR1 and DR2 are perpendicular to each other. The third direction DR3 is perpendicular to the first and second directions DR1 and DR2. The third direction DR3 is perpendicular to the top surface 200a of the package substrate 200. In the following description, the terms “top surface,” “upper side,” “bottom surface,” “lower side,” “height,” and “thickness” are defined with respect to the third direction DR3.

In some embodiments, the package substrate 200 may include a trench 200T. The trench 200T extends from the top surface 200a toward the bottom surface 200b of the package substrate 200. The bottom surface of the trench 200T may be situated within the package substrate 200.

The package substrate 200 may include a base substrate and a multilayer or single-layer wiring pattern within the base substrate. The wiring pattern may be electrically connected to package connection terminals 208, first connection terminals 318, and fourth connection terminals 418. The base substrate may be formed of at least one material selected from a phenolic resin, an epoxy resin, and polyimide. The package substrate 200 may be, for example, a printed circuit board (PCB).

The package substrate 200 may be installed on the main board 100. The package connection terminals 208 may be disposed on the bottom surface 200b of the package substrate 200. The package substrate 200 may be electrically connected to the main board 100 through the package connection terminals 208.

The package connection terminals 208 may include, for example, solder layers. The package connection terminals 208 may have various shapes such as a land, ball, pin, or pillar shape. The package connection terminals 208 may include, for example, tin (Sn), indium (In), bismuth (Bi), antimony (Sb), copper (Cu), silver (Ag), zinc (Zn), lead (Pb), and/or an alloy thereof. The number and arrangement of, and the spacing between, the package connection terminals 208 are not particularly limited and may vary depending on the design.

The first and second chip structures 300 and 400 may be disposed on the package substrate 200. The number and arrangement of the first and second chip structures 300 and 400 are not particularly limited and may vary depending on the design.

In some embodiments, one of the first and second chip structures 300 and 400 may be disposed on the top surface 200a of the package substrate 200, and the other chip structure may be disposed on the trench 200T.

In some embodiments, the first chip structure 300 may be disposed on the top surface 200a of the package substrate 200, and the second chip structure 400 may be disposed on the trench 200T. At least part of the second chip structure 400 may be disposed within the trench 200T. A first buffer chip 310 may be disposed on a second buffer chip 410.

The first chip structure 300 may include the first buffer chip 310 and a plurality of first semiconductor chips 330.

The first buffer chip 310 may be disposed on the top surface 200a of the package substrate 200. The first buffer chip 310 may include a test logic circuit such as a serial-parallel conversion circuit, a design for test (DFT), a joint test action group (JTAG), or a memory built-in self-test (MBIST) or a signal interface circuit like a physical layer (PHY). The first buffer chip 310 may transmit or receive signals and/or data through the signal interface circuit such as a PHY.

Multiple first semiconductor chips 330 may be stacked on the first buffer chip 310. The first semiconductor chips 330 may be stacked in the third direction DR3. The number of first semiconductor chips 330 may vary.

The first semiconductor chips 330 may be memory chips. For example, the first semiconductor chips 330 may be volatile memories such as dynamic random-access memories (DRAMs) or static random access memories (SRAMs) or non-volatile memories such as flash memories, phase-change random-access memories (PRAMs), magneto-resistive random-access memories (MRAMs), ferroelectric random-access memories (FeRAMs), or resistive random-access memories (RRAMs).

The first buffer chip 310 and the first semiconductor chips 330 may form a high-bandwidth memory (HBM). The first buffer chip 310 may also be referred to as a master chip or HBM controller die, while the first semiconductor chips 330 may also be referred to as memory chips, slave chips, DRAM dices, or DRAM slices. The number of first semiconductor chips 330 included in an HBM is not limited and may vary. For example, the number of first semiconductor chips 330 included in an HBM may be four or greater.

The first buffer chip 310 may include a first PHY region 320 and second through electrodes 326.

The first PHY region 320 may include a signal interface circuit such as a PHY. The first PHY region 320 may be exposed by the bottom surface of the first buffer chip 310. The first PHY region 320 includes the second through electrode 326. The second through electrodes 326 may penetrate at least some portions of the first PHY region 320 from the bottom surface of the first PHY region 320 in the third direction DR3. The bottom surfaces of the second through electrodes 326 may be exposed.

First through electrodes 316 may penetrate at least some portions of the first buffer chip 310 in the third direction DR3.

The first connection terminals 318 may be disposed on the underside of the first buffer chip 310. The first connection terminals 318 may be disposed between the first buffer chip 310 and the package substrate 200. The first connection terminals 318 may also be disposed between the top surface 200a of the package substrate 200 and the bottom surface of the first buffer chip 310. The first buffer chip 310 and the package substrate 200 may be electrically connected through the first connection terminals 318. The first connection terminals 318 may be in contact with the first through electrodes 316.

First semiconductor chips 330 may include third through electrodes 336. The third through electrodes 336 may penetrate at least some portions of the first semiconductor chips 330 in the third direction DR3. For example, the first semiconductor chips 330 may all include the third through electrode 336. In another example, all the first semiconductor chips 330, except for that arranged at the top, may include the third through electrodes 336.

Third connection terminals 338 may be disposed on the bottom surfaces of the first semiconductor chips 330. The third connection terminals 338 may be disposed between neighboring first semiconductor chips 330. The neighboring first semiconductor chips 330 may be electrically connected through the third connection terminals 338. The third connection terminals 338 may be in contact with the third through electrodes 336.

The third connection terminals 338 may be disposed between the first buffer chip 310 and the lowermost first semiconductor chip 330. The first buffer chip 310 and the lowermost first semiconductor chip 330 may be electrically connected through the third connection terminals 338. The third connection terminals 338 may be in contact with the first through electrodes 316 and the third through electrodes 336 of the lowermost first semiconductor chip 330.

The second chip structure 400 may include a second buffer chip 410 and a second semiconductor chip 430.

The second buffer chip 410 may be disposed on the trench 200T of the package substrate 200. The second buffer chip 410 may be disposed within the trench 200T. The second buffer chip 410 may include a test logic circuit such as a serial-parallel conversion circuit, a DFT, a JTAG, or an MBIST or a signal interface circuit such as a PHY. The second buffer chip 410 may transmit or receive signals and/or data through the signal interface circuit such as a PHY.

The second semiconductor chip 430 may be disposed on the second buffer chip 410. The second semiconductor chip 430 may be a processor (or host) such as a central processing unit (CPU), a graphics processing unit (GPU), a system-on-chip (SoC), or an application-specific integrated circuits (ASIC).

The second buffer chip 410 may include a second PHY region 420 and fourth through electrodes 426.

The second PHY region 420 includes a signal interface circuit such as a PHY. The second PHY region 420 may be exposed by the top surface of the second buffer chip 410. The second PHY region 420 includes the fourth through electrodes 426. The fourth through electrodes 426 may penetrate at least some portions of the second PHY region 420 from the top surface of the second PHY region 420 in the opposite direction of the third direction DR3. The top surface of the fourth through electrode 426 may be exposed.

The first through electrodes 316, the second through electrodes 326, the third through electrodes 336, and the fourth through electrodes 426 may include a conductive material. The numbers and arrangements of, and the spacings between, the first through electrodes 316, the second through electrodes 326, the third through electrodes 336, and the fourth through electrodes 426 are not particularly limited and may vary depending on the design.

At least some portions of the second chip structure 400 may overlap with the first chip structure 300 in the third direction DR3. At least some portions of the second buffer chip 410 may overlap with the first buffer chip 310 in the third direction DR3. The second PHY region 420 of the second buffer chip 410 may overlap with the first PHY region 320 of the first buffer chip 310 in the third direction DR3.

In some embodiments, the first buffer chip 310 may be disposed on both the package substrate 200 and the second buffer chip 410. The first and second buffer chips 310 and 410 may have or define a stepped shape. The second semiconductor chip 430 may be spaced apart from the first buffer chip 310, on the second buffer chip 410 (e.g., the second semiconductor chip 430 may be horizontally spaced apart from the first buffer chip 310).

The second connection terminals 328 may be disposed on the bottom surface of the first buffer chip 310. The second connection terminals 328 may be disposed between the first and second buffer chips 310 and 410. The first and second buffer chips 310 and 410 may be electrically connected through the second connection terminals 328. The second connection terminals 328 may be in contact with the second through electrodes 326 and the fourth through electrodes 426. The first and second buffer chips 310 and 410 may be electrically connected through the first and second PHY regions 320 and 420. The first and second buffer chips 310 and 410 may transmit and receive signals through the first and second PHY regions 320 and 420.

In some embodiments, the first and second PHY regions 320 and 420 overlap with each other in the third direction DR3 and are directly connected through the second connection terminals 328. Accordingly, the distance between the first and second PHY regions 320 and 420 decreases, leading to decreased RC delays and signal latencies. As a result, a semiconductor package with an improved data processing speed can be provided. Additionally, the first and second chip structures 300 and 400 may be connected to each other without the aid of a separate interposer.

The height of the second connection terminals 328 may differ from the height of the first connection terminals 318, depending on the thickness of the second buffer chip 410. For example, if the top surface of the second buffer chip 410 is positioned higher than the top surface 200a of the package substrate 200, the height of the second connection terminals 328 may be less than the height of the first connection terminals 318.

Fourth connection terminals 418 may be disposed on the bottom surface of the second buffer chip 410. The fourth connection terminals 418 may be disposed within the trench 200T of the package substrate 200. The fourth connection terminals 418 may be disposed between the second buffer chip 410 and the package substrate 200. The fourth connection terminals 418 may electrically connect the second buffer chip 410 and the package substrate 200.

Fifth connection terminals 438 may be disposed on the bottom surface of the second semiconductor chip 430. The fifth connection terminals 438 may be disposed between the second buffer chip 410 and the second semiconductor chip 430. The fifth connection terminals 438 may electrically connect the second buffer chip 410 and the second semiconductor chip 430.

The first connection terminals 318, the second connection terminals 328, the third connection terminals 338, the fourth connection terminals 418, and the fifth connection terminals 438 may include, for example, spherical or ball-shaped solder layers, and may have various shapes. The first connection terminals 318, the second connection terminals 328, the third connection terminals 338, the fourth connection terminals 418, and the fifth connection terminals 438 may include, for example, Sn, In, Bi, Sb, Cu, Ag, Zn, Pb, and/or an alloy thereof. The first connection terminals 318, the second connection terminals 328, the third connection terminals 338, the fourth connection terminals 418, and the fifth connection terminals 438 may have a pillar structure. The pillar structure may include, for example, nickel (Ni), a Ni alloy, Cu, a Cu alloy, palladium (Pd), platinum (Pt), gold (Au), cobalt (Co), or a combination thereof. The pillar structure may consist of one metal layer or stacks of multiple metal layers. The numbers and arrangements of, and the spacings between, the first connection terminals 318, the second connection terminals 328, the third connection terminals 338, the fourth connection terminals 418, and the fifth connection terminals 438 are not particularly limited and may vary depending on the design.

The thermal transfer material layer 440 may be disposed on the second chip structure 400. In some embodiments, the thermal transfer material layer 440 may be disposed on a top surface 400us of the second chip structure 400. The thermal transfer material layer 440 may be in contact with the top surface 400us of the second chip structure 400.

The thermal transfer material layer 440 may include, for example, a thermal interface material (TIM). The thermal transfer material layer 440 may include at least one metal material selected from among, for example, Ag, aluminum (Al), Cu, Au, Zn, Ni, and iron (Fe), or an alloy of the at least one metal material.

The first heat dissipation member 480 may be disposed on the thermal transfer material layer 440. The first heat dissipation member 480 and the second chip structure 400 may be attached to each other by the thermal transfer material layer 440.

The first heat dissipation member 480 may be, for example, a heat sink, a heat spreader, or a heat pipe. The first heat dissipation member 480 may include, for example, Ag, Cu, Ni, Au, or a combination thereof.

The second chip structure 400 may dissipate a significant amount of heat compared to the first chip structure 300. The first heat dissipation member 480 may dissipate heat emitted from the second chip structure 400 through the thermal transfer material layer 440. For example, the first heat dissipation member 480 may transfer the heat emitted from the second chip structure 400 to a second heat dissipation member 600. Consequently, the reliability and operational performance of the semiconductor package according to some embodiments of the present disclosure can be improved.

The thickness of the second chip structure 400 may be smaller than the thickness of the first chip structure 300. The top surface 400US of the second chip structure 400 may be lower than a top surface 300us of the first chip structure 300. Relative to the top surface 200a of the package substrate 200, the height of the top surface 400US of the second chip structure 400 may be less than the height of the top surface 300us of the first chip structure 300. The thermal transfer material layer 440 and the first heat dissipation member 480 may be disposed on the second chip structure 400, and the top surface 300us of the first chip structure 300 may be on the same plane as a top surface 480us of the first heat dissipation member 480. The height from the top surface 300us of the first chip structure 300 to the top surface 200a of the package substrate 200 may be equal to the height from the top surface 480US of the first heat dissipation member 480 to the top surface 200a of the package substrate 200. Consequently, warpage of the semiconductor package according to some embodiments of the present disclosure that may be caused by the difference in thickness between the first and second chip structures 300 and 400 can be improved or prevented.

The molding layer 500 may be disposed on the package substrate 200. The molding layer 500 may be disposed on the top surface 200a of the package substrate 200. The molding layer 500 may at least partially cover, surround, or be on the top surface 200a of the package substrate 200, the top surface 300us of the first chip structure 300, the top surface 400us of the second chip structure 400, the thermal transfer material layer 440 (e.g., side surfaces thereof), and the top surface 480US of the first heat dissipation member 480. The molding layer 500 may also cover the top surface 300us of the first chip structure 300 and the top surface 480US of the first heat dissipation member 480. The molding layer 500 may encapsulate the first chip structure 300, the second chip structure 400, the thermal transfer material layer 440, and the first heat dissipation member 480. The molding layer 500 may at least partially fill or be in the space between the package substrate 200 and the second buffer chip 410.

The molding layer 500 may include an insulating polymer material such as an epoxy molding compound (EMC), but the present disclosure is not limited thereto.

The second heat dissipation member 600 may be disposed on the molding layer 500. The second heat dissipation member 600 may dissipate heat from within the semiconductor package according to some embodiments of the present disclosure to the outside. For example, the second heat dissipation member 600 may include multiple grooves to more efficiently dissipate heat. For example, the second heat dissipation member 600 may be attached to the molding layer 500. In another example, an additional thermal transfer material layer may be further disposed between the second heat dissipation member 600 and the molding layer 500.

The second heat dissipation member 600 may be a heat sink, heat spreader, or heat pipe. The second heat dissipation member 600 may include, for example, a metallic material, a ceramic material, a carbon-based material, or a polymer-based material.

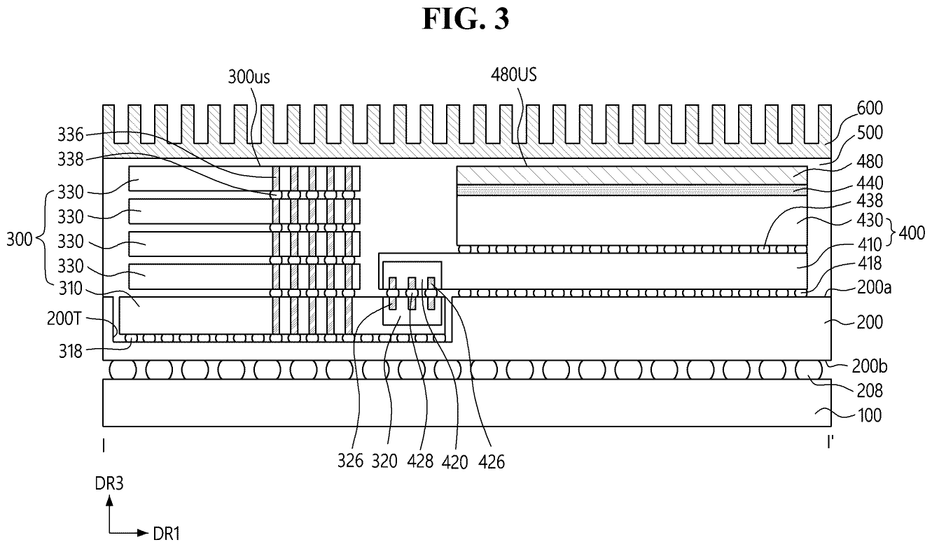

FIGS. 3 through 5 are cross-sectional views of semiconductor packages according to some embodiments of the present disclosure. Specifically, FIGS. 3 through 5 are cross-sectional views taken along lines I-I′ of FIG. 1. For convenience, the embodiments of FIGS. 3 through 5 will hereinafter be described, highlighting the differences with the embodiment of FIGS. 1 and 2.

Referring to FIG. 3, a first chip structure 300 may be disposed on a trench 200T, and a second chip structure 400 may be disposed on a top surface 200a of a package substrate 200. At least some portions of the first chip structure 300 may be disposed within the trench 200T. A second buffer chip 410 may be disposed on a first buffer chip 310.

The first buffer chip 310 may be disposed on the trench 200T of the package substrate 200. The first buffer chip 310 may be disposed within the trench 200T. First connection terminals 318 may be disposed within the trench 200T.

A first PHY region 320 may be exposed by the top surface of the first buffer chip 310. Second through electrodes 326 may penetrate at least some portions of the first PHY region 320 from the top surface of the first PHY region 320 in the opposite direction of a third direction DR3. The top surfaces of the second through electrodes 326 may be exposed.

The second buffer chip 410 may be disposed on the top surface 200a of the package substrate 200. The second buffer chip 410 may be disposed on both the first surface 200a of the package substrate 200 and the first buffer chip 310. The second buffer chip 410 may be spaced apart from the first semiconductor chip 330, on the first buffer chip 310 (e.g., the second buffer chip 410 may be horizontally spaced apart from the first semiconductor chip 330). Fourth connection terminals 418 may be disposed between the top surface 200a of the package substrate 200 and the second buffer chip 410.

A second PHY region 420 may be exposed by the bottom surface of the second buffer chip 410. Fourth through electrodes 426 may penetrate at least some portions of the second PHY region 420 from the bottom surface of the second buffer chip 410 in the third direction DR3. The bottom surfaces of the fourth through electrodes 426 may be exposed.

Fifth connection terminals 428 may be disposed on the bottom surface of the second buffer chip 410. The fifth connection terminals 428 may be disposed between the first and second buffer chips 310 and 410. The first and second buffer chips 310 and 410 may be electrically connected through the fifth connection terminals 428. The fifth connection terminals 428 may be in contact with the second through electrodes 326 and the fourth through electrodes 426.

The height of the fifth connection terminals 428 may differ from the height of the fourth connection terminals 418, depending on the thickness of the first buffer chip 310.

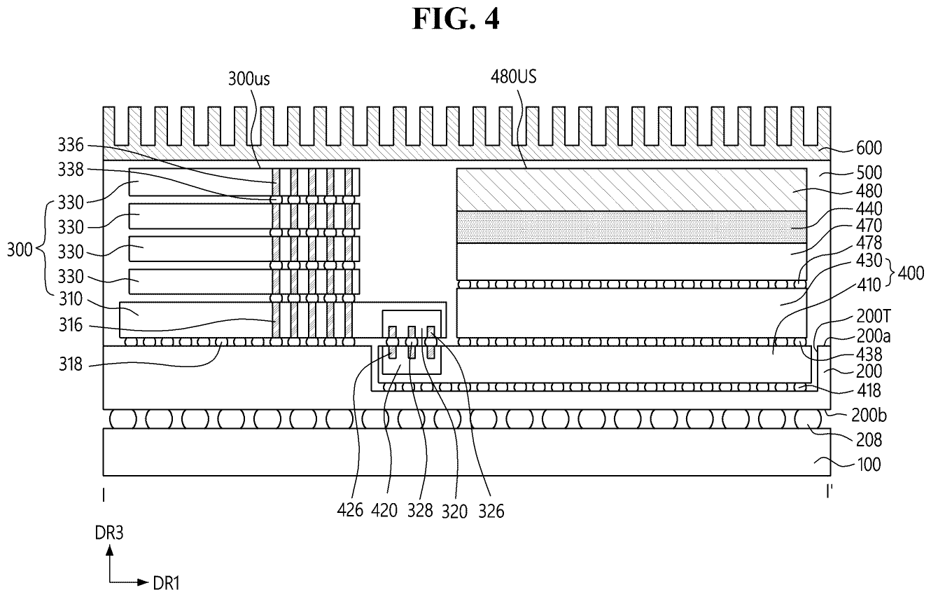

Referring to FIG. 4, the semiconductor package according to some embodiments of the present disclosure may further include a first dummy chip 470 and sixth connection terminals 478.

The first dummy chip 470 may be disposed between a second chip structure 400 and a thermal transfer material layer 440. The first dummy chip 470 may be disposed on a second semiconductor chip 430. The thermal transfer material layer 440 may be disposed on the top surface of the first dummy chip 470. The thermal transfer material layer 440 may be in contact with the top surface of the first dummy chip 470.

Sixth connection terminals 478 may be disposed on the bottom surface of the first dummy chip 470. The sixth connection terminals 478 may be disposed between the first dummy chip 470 and the second semiconductor chip 430. The first dummy chip 470 may be attached to the second semiconductor chip 430 through the sixth connection terminals 478. The sixth connection terminals 478 may include, for example, spherical or ball-shaped solder layers, and may have various shapes. The sixth connection terminals 478 may have, for example, a pillar structure. The number and arrangement of, and the spacing between, the sixth connection terminals 478 are not particularly limited and may vary depending on the design.

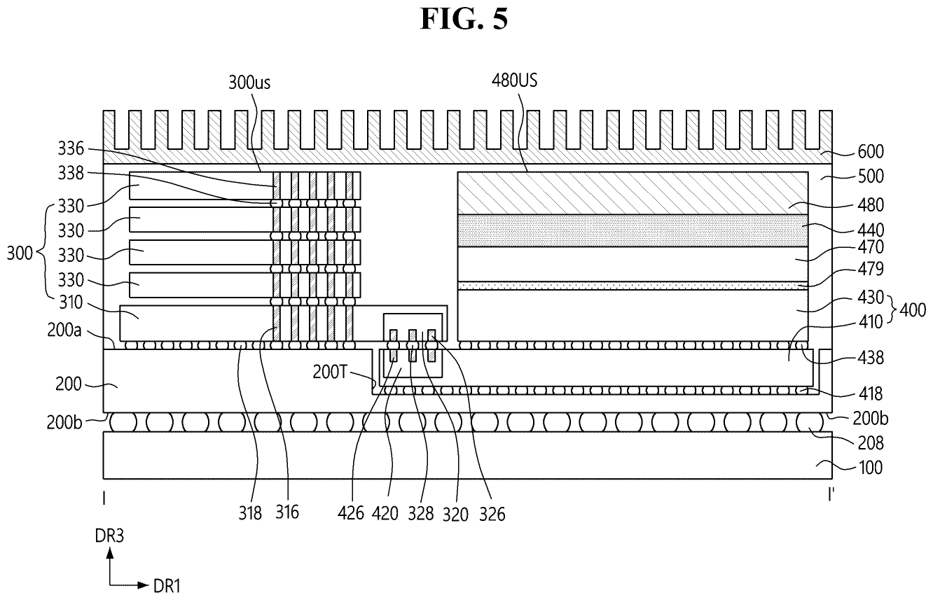

Referring to FIG. 5, the semiconductor package according to some embodiments of the present disclosure may further include a first dummy chip 470 and an adhesive layer 479.

The first dummy chip 470 may be disposed between a second chip structure 400 and a thermal transfer material layer 440. The first dummy chip 470 may be disposed on a second semiconductor chip 430. The thermal transfer material layer 440 may be disposed on the top surface of the first dummy chip 470. The thermal transfer material layer 440 may be in contact with the top surface of the first dummy chip 470.

The adhesive layer 479 may be disposed on the bottom surface of the first dummy chip 470. The adhesive layer 479 may be disposed between the first dummy chip 470 and the second semiconductor chip 430. The first dummy chip 470 may be attached to the second semiconductor chip 430 through the adhesive layer 479. The adhesive layer 479 may include, for example, a direct adhesive film (DAF).

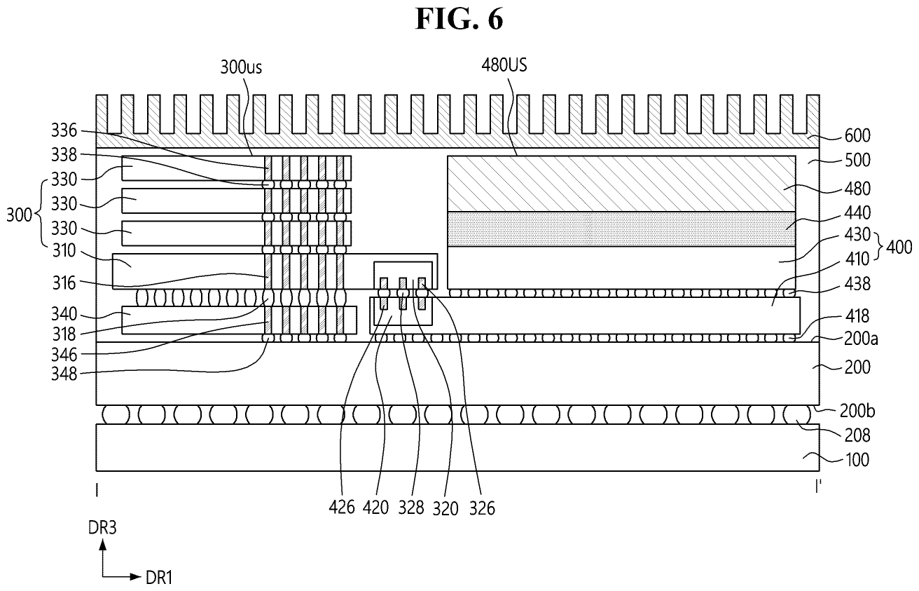

FIG. 6 is a cross-sectional view of a semiconductor package according to some embodiments of the present disclosure. Specifically, FIG. 6 is a cross-sectional view taken along line I-I′ of FIG. 1. For convenience, the embodiment of FIG. 6 will hereinafter be described, highlighting the differences with the embodiments of FIGS. 1 through 5.

Referring to FIG. 6, a package substrate 200 may not include a trench (“200T” of FIG. 2). A top surface 200a of the package substrate 200 may be flat or planar with no step difference.

In some embodiments, the semiconductor package according to some embodiments of the present disclosure may include a third semiconductor chip 340.

The third semiconductor chip 340 may be a memory chip. For example, the third semiconductor chip 340 may be a volatile memory such as a DRAM or an SRAM or may be a non-volatile memory such as a flash memory, a PRAM, an MRAM, a FeRAM, or an RRAM.

In some embodiments, a first chip structure 300 and the third semiconductor chip 340 may form an HBM. The numbers of first semiconductor chips 330 and third semiconductor chips 340 constituting an HBM is not particularly limited and may vary. For example, there may be provided one third semiconductor chip 340 and three or more first semiconductor chips 330.

In some embodiments, the first chip structure 300 and a second chip structure 400 may be disposed on a top surface 200a of the package substrate 200.

The third semiconductor chip 340 may be disposed on the top surface 200a of the package substrate 200. The third semiconductor chip 340 may be disposed between the package substrate 200 and the first chip structure 300. The first chip structure 300 may be disposed on the third semiconductor chip 340. A first buffer chip 310 may be disposed on the third semiconductor chip 340. First connection terminals 318 may be disposed between the first buffer chip 310 and the third semiconductor chip 340. The first buffer chip 310 and the third semiconductor chip 340 may be electrically connected through the first connection terminals 318. The first connection terminals 318 may be in contact with first through electrodes 316.

A second buffer chip 410 may be spaced apart from the third semiconductor chip 340, on the top surface 200a of the package substrate 200 (e.g., the second buffer chip 410 may be horizontally spaced apart from the third semiconductor chip 340). The second buffer chip 410 and the first buffer chip 310 may have or define a stepped shape. The second semiconductor chip 430 may be spaced apart from the first buffer chip 310, on the second buffer chip 410.

The third semiconductor chip 340 may include fourth through electrodes 346. The fourth through electrodes 346 may penetrate at least some portions of the third semiconductor chip 340 in a third direction DR3. For example, the fourth through electrodes 346 may penetrate the third semiconductor chip 340 fully. Alternatively, the fourth through electrodes 346 may penetrate the third semiconductor chip 340 only partially from the top surface toward the bottom surface of the third semiconductor chip 340. The fourth through electrodes 346 may include a conductive material. The number and arrangement of, and the spacing between, the fourth through electrodes 346 are not particularly limited and may vary based on the design.

Seventh connection terminals 348 may be disposed on the bottom surface of the third semiconductor chip 340. The seventh connection terminals 348 may be disposed between the third semiconductor chip 340 and the top surface 200a of the package substrate 200. The third semiconductor chip 340 and the package substrate 200 may be electrically connected through the seventh connection terminals 348. The seventh connection terminals 348 may include spherical or ball-shaped solder layers and may have various shapes. Additionally, the seventh connection terminals 348 may have a pillar structure. The number and arrangement of, and the spacing between, the seventh connection terminals 348 are not particularly limited and may vary based on the design.

The height of the first connection terminals 318 may differ from the height of the second connection terminals 328, depending on the thickness of the third semiconductor chip 340.

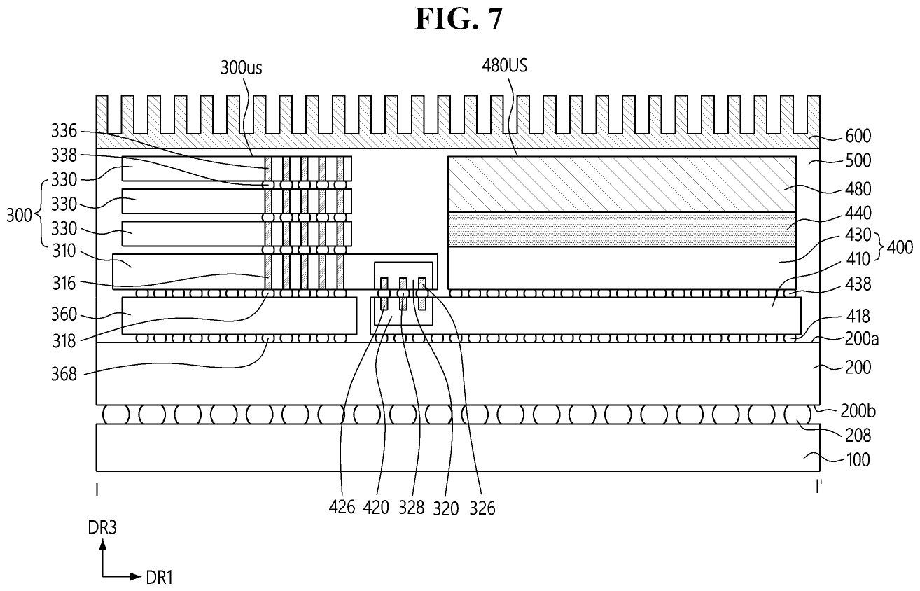

FIGS. 7 through 9 are cross-sectional views of semiconductor packages according to some embodiments of the present disclosure. Specifically, FIGS. 7 through 9 are cross-sectional views taken along lines I-I′ of FIG. 1. For convenience, the embodiments of FIGS. 7 through 9 will hereinafter be described, highlighting the differences with the embodiment of FIG. 6.

Referring to FIG. 7, the semiconductor package according to some embodiments of the present disclosure may further include a second dummy chip 360 and eighth connection terminals 368, instead of the third semiconductor chip 340 and the seventh connection terminals 348 of FIG. 6.

The second dummy chip 360 may be disposed on a top surface 200a of a package substrate 200. A second buffer chip 410 may be spaced apart from the second dummy chip 360, on the top surface 200a of the package substrate 200 (e.g., the second buffer chip 410 may be horizontally spaced apart from the second dummy chip 360). A first buffer chip 310 may be disposed on the second buffer chip 410.

The eighth connection terminals 368 may be disposed on the bottom surface of the second dummy chip 360. The eighth connection terminals 368 may be disposed between the second dummy chip 360 and the top surface 200a of the package substrate 200. The eighth connection terminals 368 may include, for example, spherical or ball-shaped solder layers and may have various shapes. Additionally, the eighth connection terminals 368 may have a pillar structure. The number and arrangement of, and the spacing between, the eighth connection terminals 368 are not particularly limited and may vary based on the design.

The second dummy chip 360 may be disposed between the top surface 200a of the package substrate 200 and a first chip structure 300. The first chip structure 300 may be disposed on the second dummy chip 360. The first buffer chip 310 may be disposed on the second dummy chip 360.

The height of first connection terminals 318 may differ from the height of second connection terminals 328, depending on the thickness of the second dummy chip 360.

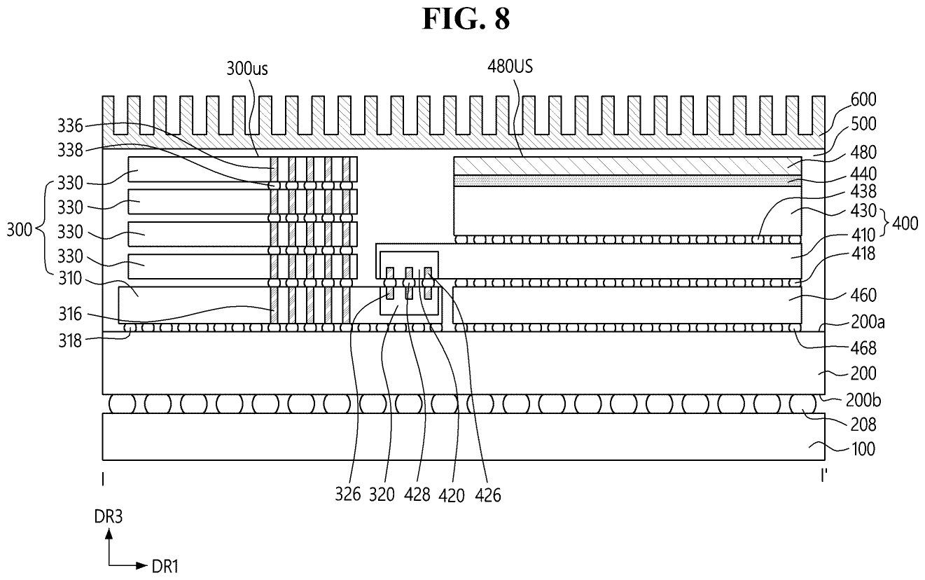

Referring to FIG. 8, the semiconductor package according to some embodiments of the present disclosure may include a third dummy chip 460 and ninth connection terminals 468, instead of the third semiconductor chip 340 and the seventh connection terminals 348 of FIG. 6.

The third dummy chip 460 may be disposed on a top surface 200a of a package substrate 200. A first buffer chip 310 may be spaced apart from the third dummy chip 460, on the top surface 200a of the package substrate 200 (e.g., the first buffer chip 310 may be horizontally spaced apart from the third dummy chip 460). A second buffer chip 410 may be disposed on the first buffer chip 310.

Ninth connection terminals 468 may be disposed on the bottom surface of the third dummy chip 460. The ninth connection terminals 468 may be disposed between the third dummy chip 460 and the top surface 200a of the package substrate 200. The ninth connection terminals 468 may include, for example, spherical or ball-shaped solder layers and may have various shapes. Additionally, the ninth connection terminals 468 may have a pillar structure. The number and arrangement of, and the spacing between, the ninth connection terminals 468 are not particularly limited and may vary based on the design.

The height of fourth connection terminals 418 may differ from the height of fifth connection terminals 428, depending on the thickness of the third dummy chip 460.

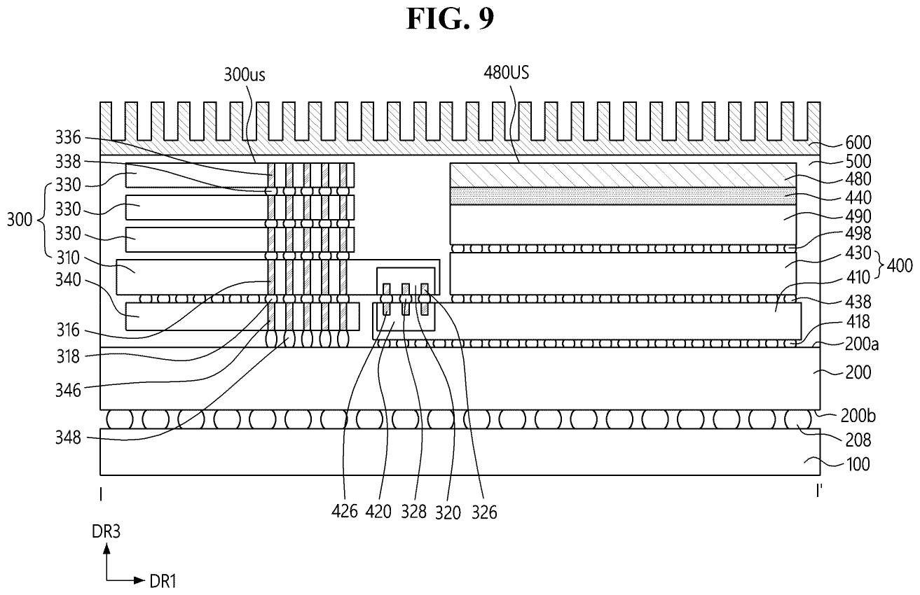

Referring to FIG. 9, the semiconductor package according to some embodiments of the present disclosure may further include a fourth dummy chip 490 and tenth connection terminals 498. The fourth dummy chip 490 and the tenth connection terminals 498 of FIG. 9 may be similar to the first dummy chip 470 and the sixth connection terminals 478, respectively, of FIG. 4.

The fourth dummy chip 490 may be attached to a second semiconductor chip 430 through an adhesive layer, instead of through the tenth connection terminals 498.

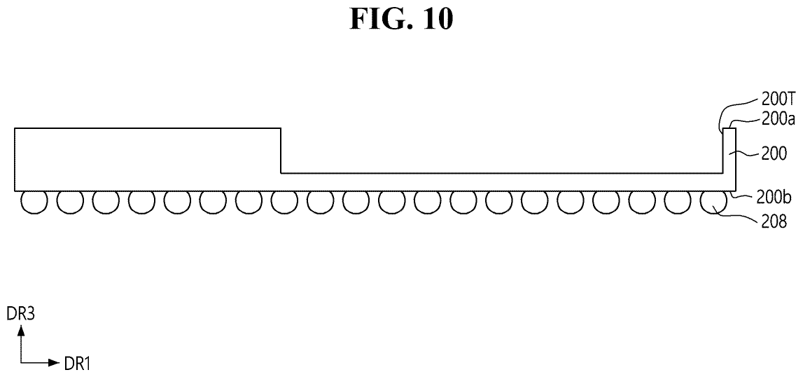

FIGS. 10 through 13 are cross-sectional views illustrating intermediate steps of a method of fabricating a semiconductor package according to some embodiments of the present disclosure. For convenience, the embodiment of FIGS. 10 through 13 will hereinafter be described, highlighting the differences with the embodiments of FIGS. 1 through 9.

Referring to FIG. 10, a package substrate 200 having a top surface 200a and a bottom surface 200b is provided. Package connection terminals 208 may be formed on the bottom surface 200b of the package substrate 200.

A trench 200T may be formed within the package substrate 200. The trench 200T may be formed from the top surface 200a toward the bottom surface 200b of the package substrate 200. The bottom surface of the trench 200T may be positioned within the package substrate 200 (e.g., above the bottom surface 200b of the package substrate 200).

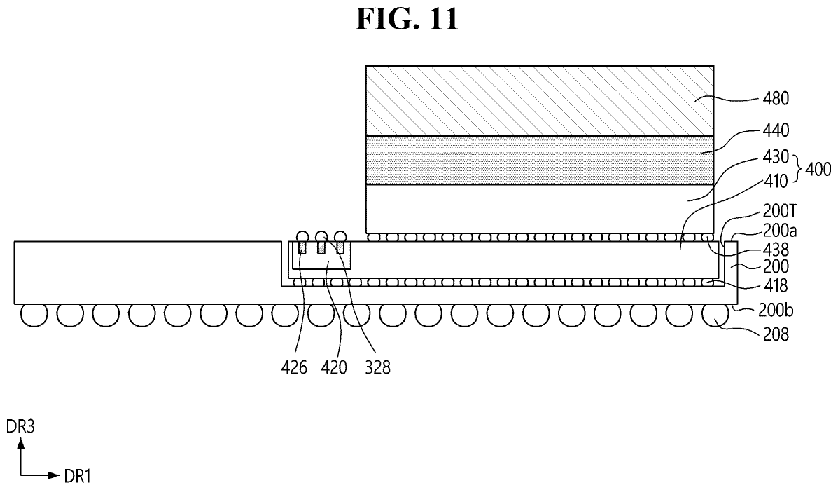

Referring to FIG. 11, a second chip structure 400, a thermal transfer material layer 440, and a first heat dissipation member 480 may be mounted on the trench 200T of the package substrate 200.

A second buffer chip 410 may be mounted within the trench 200T. Fourth connection terminals 418 may be formed on the bottom surface of the second buffer chip 410. A second semiconductor chip 430 may be mounted on the second buffer chip 410. Fifth connection terminals 438 may be formed on the bottom surface of the second semiconductor chip 430. The second semiconductor chip 430 may not overlap with a second PHY region 420 of the second buffer chip 410 in a third direction DR3. The second PHY region 420 may be exposed by the second semiconductor chip 430. Second connection terminals 328 may be formed in the second PHY region 420. The second connection terminals 328 may be connected to fourth through electrodes 426.

The thermal transfer material layer 440 and the first heat dissipation member 480 may be disposed on the second chip structure 400.

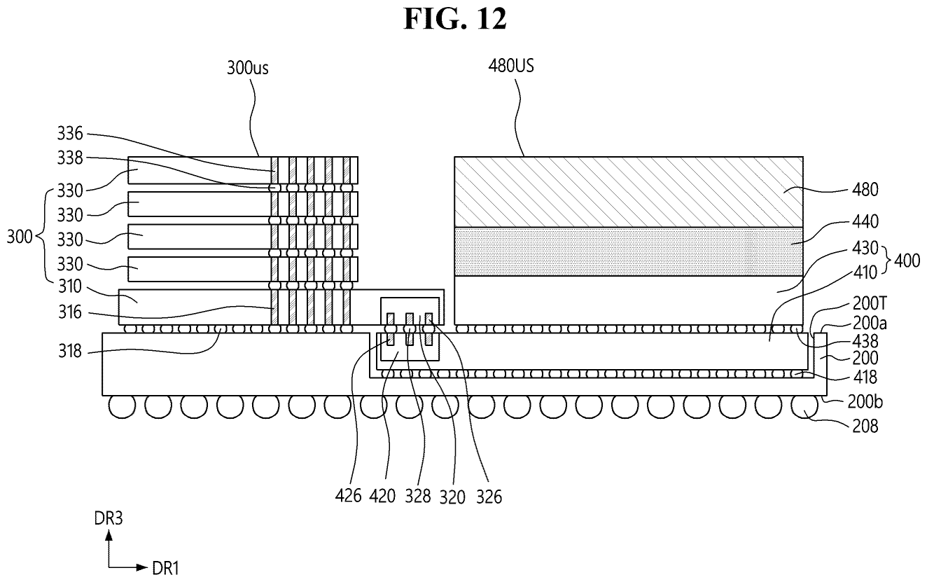

Referring to FIG. 12, a first chip structure 300 may be mounted on the top surface 200a of the package substrate 200.

A first buffer chip 310 may be mounted on the package substrate 200 so that a first PHY region 320 and the second PHY region 420 overlap with each other in the third direction DR3. The first and second PHY regions 320 and 420 may be connected by the second connection terminals 328. The second connection terminals 328 may be connected to second through electrodes 326. A plurality of first semiconductor chips 330 may be mounted on the first buffer chip 310.

Thereafter, referring again to FIG. 2, a molding layer 500 and a second heat dissipation member 600 may be formed.

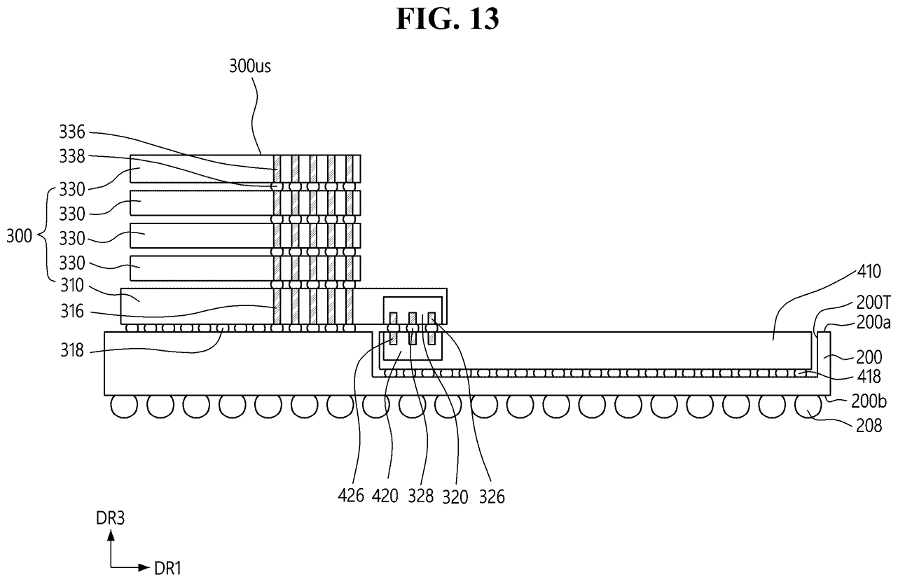

FIG. 13 is a cross-sectional view illustrating a step to be performed after that depicted in FIG. 10. After the step depicted in FIG. 13, the step depicted in FIG. 12 may be performed.

Referring to FIG. 13, a second buffer chip 410 may be mounted on the trench 200T of the package substrate 200. The first chip structure 300 may be mounted on both the top surface 200a of the package substrate 200 and the second buffer chip 410. The first chip structure 300 may be mounted on the top surface 200a of the package substrate 200 and the second buffer chip 410 so that the first PHY region 320 of the first buffer chip 310 and the second PHY region 420 of the second buffer chip 410 overlap with each other in the third direction DR3.

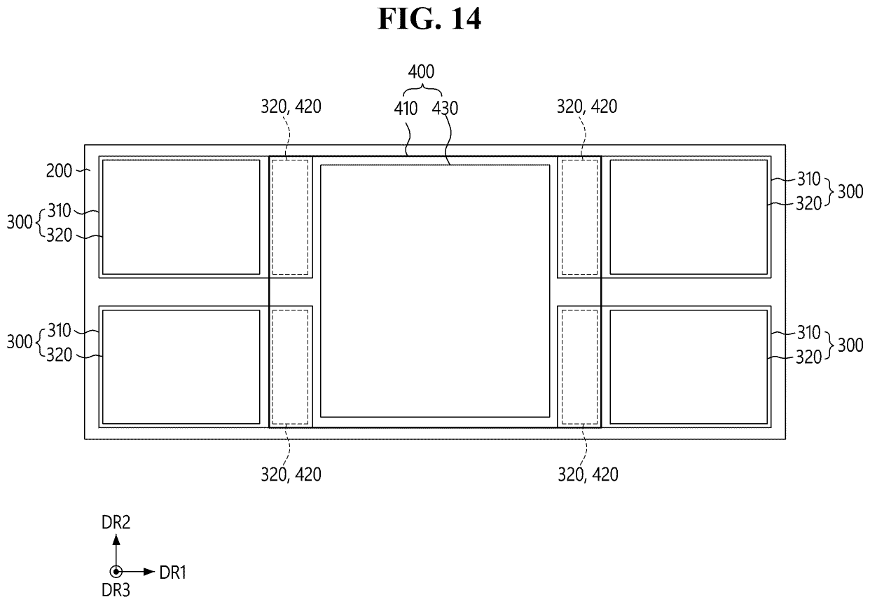

FIG. 14 is a plan view of a semiconductor package according to some embodiments of the present disclosure. For convenience, the embodiment of FIG. 14 will hereinafter be described, highlighting the differences with the embodiments of FIGS. 1 through 9.

Referring to FIG. 14, the semiconductor package according to some embodiments of the present disclosure may include a plurality of first chip structures 300 and a second chip structure 400. The first chip structures 300 and the second chip structure 400 may be disposed on a package substrate 200. The first chip structures 300 may be disposed around the second chip structure 400.

For example, four first chip structures 300 may be disposed around the second chip structure 400. Two first chip structures 300 may be disposed on either side of the second chip structure 400 in a first direction DR1.

The first chip structures 300 and the second chip structure 400 may correspond to the first chip structure 300 and the second chip structure 400, respectively, of any one of FIGS. 1 through 9.

Alternatively, the semiconductor package according to some embodiments of the present disclosure may include a plurality of first chip structures 300 and a plurality of second chip structures 400. The first chip structures 300 may be disposed around each of the second chip structures 400.

Embodiments of the present disclosure have been described above with reference to the accompanying drawings, but the present disclosure is not limited thereto and may be implemented in various different forms. It will be understood that the present disclosure can be implemented in other specific forms without changing the technical spirit or scope of the present disclosure. Therefore, it should be understood that the embodiments set forth herein are illustrative in all respects and not limiting.

What is claimed is:

1. A semiconductor package comprising:
a package substrate including a trench;
a first chip structure including a first buffer chip and a plurality of first semiconductor chips on the first buffer chip; and
a second chip structure including a second buffer chip and a second semiconductor chip on the second buffer chip,
wherein
one of the first and second chip structures is on the trench,
the other one of the first and second chip structures is on a top surface of the package substrate, and
a first physical layer (PHY) region of the first buffer chip overlaps with a second PHY region of the second buffer chip in a direction perpendicular to the top surface of the package substrate.

2. The semiconductor package of claim 1, wherein
one of the first and second buffer chips is in the trench, and
the other one of the first and second buffer chips is on the top surface of the package substrate.

3. The semiconductor package of claim 1, further comprising:
a connection terminal in contact with the first and second PHY regions.

4. The semiconductor package of claim 3, wherein
the first PHY region includes first through via therein,
the second PHY region includes second through via therein, and
the first through via and the second through via are in contact with the connection terminal.

5. The semiconductor package of claim 1, further comprising:
a thermal transfer material layer on the second semiconductor chip; and
a heat dissipation member on the thermal transfer material layer.

6. The semiconductor package of claim 5, wherein a top surface of the first chip structure is on the same plane as a top surface of the heat dissipation member.

7. The semiconductor package of claim 5, further comprising:
a dummy chip between the second semiconductor chip and the thermal transfer material layer; and
a connection terminal between the dummy chip and the second semiconductor chip.

8. The semiconductor package of claim 5, further comprising:
a dummy chip between the second semiconductor chip and the thermal transfer material layer; and
an adhesive layer between the dummy chip and the second semiconductor chip.

9. A semiconductor package comprising:
a package substrate;
a first chip structure including a first buffer chip and a plurality of first semiconductor chips on the first buffer chip;
a second chip structure including a second buffer chip and a second semiconductor chip on the second buffer chip; and
a third semiconductor chip on a top surface of the package substrate,
wherein
one of the first and second chip structures is on the top surface of the package substrate,
the other one of the first and second chip structures is on the third semiconductor chip, and
a first physical layer (PHY) region of the first buffer chip overlaps with a second PHY region of the second buffer chip in a direction perpendicular to the top surface of the package substrate.

10. The semiconductor package of claim 9, further comprising:
a connection terminal in contact with the first and second PHY regions.

11. The semiconductor package of claim 9, wherein
the first chip structure is on the top surface of the package substrate,
the second chip structure is on the third semiconductor chip, and
the third semiconductor chip is a dummy chip.

12. The semiconductor package of claim 9, wherein
the first chip structure is on the third semiconductor chip,
the second chip structure is on the package substrate, and
the third semiconductor chip is a memory chip.

13. The semiconductor package of claim 9, wherein
the first chip structure is on the third semiconductor chip,
the second chip structure is on the package substrate, and
the third semiconductor chip is a dummy chip.

14. The semiconductor package of claim 9, further comprising:
a thermal transfer material layer on the second semiconductor chip; and
a heat dissipation member on the thermal transfer material layer.

15. The semiconductor package of claim 14, wherein a top surface of the first chip structure is coplanar with a top surface of the heat dissipation member.

16. The semiconductor package of claim 14, further comprising:
a dummy chip between the second semiconductor chip and the thermal transfer material layer.

17. A semiconductor package comprising:
a package substrate including a trench;
a first chip structure on the package substrate, the first chip structure including a first buffer chip, which includes a first physical layer (PHY) region, and a plurality of first semiconductor chips on the first buffer chip;
a second chip structure on the package substrate, the second chip structure including a second buffer chip, which includes a second PHY region, and a plurality of second semiconductor chips on the second buffer chip;
a thermal transfer material layer on the second chip structure;
a first heat dissipation member on the thermal transfer material layer;
a molding layer on the package substrate, the molding layer on the first chip structure and the first heat dissipation member; and
a second heat dissipation member on the molding layer,
wherein
the first PHY region overlaps with the second PHY region in a direction perpendicular to a top surface of the package substrate,
one of the first and second buffer chips is in the trench, and
the other one of the first and second buffer chips is on the top surface of the package substrate.

18. The semiconductor package of claim 17, wherein a top surface of the first chip structure is on the same plane as a top surface of the first heat dissipation member.

19. The semiconductor package of claim 17, wherein
the first semiconductor chips are memory chips, and
the second semiconductor chip is a processor chip.

20. The semiconductor package of claim 17, further comprising:
a dummy chip between the second chip structure and the thermal transfer material layer.
